(19) United States
(12) Patent Application Publication
(10) Pub. No.: US 2024/0355736 A1
(43) Pub. Date: Oct. 24, 2024

(54) SEMICONDUCTOR STRUCTURES AND FABRICATION METHOD THEREOF, MEMORY DEVICE AND MEMORY SYSTEM

(71) Applicant: Yangtze Memory Technologies Co., Ltd., Wuhan (CN)

(72) Inventors: Chengbao Zhou, Wuhan (CN); Min Wen, Wuhan (CN); Zhen Pan, Wuhan (CN)

(21) Appl. No.: 18/463,266

(22) Filed: Sep. 7, 2023

(30) Foreign Application Priority Data
Apr. 24, 2023 (CN) 202310451628.2

(51) Int. Cl. H01L 23/528; H01L 23/522; H10B 41/20; H10B 41/35; H10B 41/40; H10B 43/20; H10B 43/35; H10B 43/40

(52) U.S. Cl. CPC H01L 23/5283; H01L 23/5226; H10B 41/20; H10B 41/35; H10B 41/40; H10B 43/20; H10B 43/35; H10B 43/40

(57) ABSTRACT

Examples of the present disclosure propose a semiconductor structure and a fabrication method thereof, a memory device, and a memory system. The semiconductor structure includes at least one deck structure. The fabrication method of the deck structure includes: providing a first stack structure in which a peripheral circuit is disposed; forming a first contact and a second contact at least penetrating through the first stack structure; providing a second stack structure in which a memory cell array is disposed; forming a third contact and a fourth contact penetrating through the second stack structure; stacking and bonding the first stack structure and the second stack structure along a first direction to form the deck structure, wherein the first contact is connected with the third contact by bonding to form a first interconnection structure, and the second contact is connected with the fourth contact by bonding to form a second interconnection structure.

### CROSS-REFERENCE TO RELATED APPLICATION

This application claims priority to and the benefit of Chinese Patent Application 202310451628.2, filed on Apr. 24, 2023, which is hereby incorporated by reference in its entirety.

### TECHNICAL FIELD

The present disclosure relates to the technical field of semiconductors, and particularly to, but not limited to, a semiconductor structure and a fabrication method thereof, a memory device and a memory system.

### BACKGROUND

A semiconductor structure, e.g., a three-dimensional (3D) NAND memory, is applied more and more widely in electronic products due to its advantages such as low power consumption and high integration density, etc.

### BRIEF DESCRIPTION OF THE DRAWINGS

FIG. 1 is a schematic cross-sectional view of a plurality of deck structures disposed in stacks provided in examples of the present disclosure;

FIG. 2 is a schematic flow diagram of a fabrication method of a semiconductor structure provided by examples of the present disclosure;

FIGS. 3A-3J are schematic cross-sectional views of a fabrication process of a semiconductor structure provided by examples of the present disclosure; and

FIG. 4 is a schematic cross-sectional view of a semiconductor structure with a plurality of deck structures provided by examples of the present disclosure.

### DESCRIPTION OF REFERENCE NUMERALS

100—Memory; 101—Deck structure; 102—Through silicon via; 103—Micro bump; 301—First substrate; 302—First stack structure; 302a—Peripheral circuit; 302b—First dielectric layer; 303—First via; 304—Second via; 305—First contact; 306—Second contact; 401—Second substrate; 402—Second stack structure; 402a—Memory cell array; 402b—Interconnection layer; 403—Third via; 404—Fourth via; 405—Third contact; 406—Fourth contact; 501—First interconnection structure; 502—Second interconnection structure; 503—Protective layer; 503a—First protective sub-layer; 503b—Second protective sub-layer; 504—Fifth contact; 505—Sixth contact; 506—Second dielectric layer; 507—Third interconnection structure; 60a—First deck structure; 60b—Second deck structure.

In the above drawings (not necessarily drawn to scale), like reference numerals in the drawings may describe like components in different views. Like reference numerals having different letter suffixes may represent different examples of like components. The drawings illustrate generally, by way of example, but not by way of limitation, various examples as discussed herein.

### DETAILED DESCRIPTION

With the continuous development of three-dimensional NAND memory technology, the capacity of the memory is continuously increasing, and the number of stack layers of deck structures in the memory is rising. However, there are still many problems in a process of stacking a plurality of deck structures.

Implementations disclosed by the present disclosure will be described below in more detail with reference to the drawings. Although the implementations of the present disclosure are shown in the drawings, it is to be understood that the present disclosure may be achieved in various forms which should not be limited by the specific implementations as set forth herein. Rather, these implementations are provided for a more thorough understanding of the present disclosure, and can fully convey the scope disclosed by the present disclosure to those skilled in the art.

In the following description, numerous specific details are presented to provide a more thorough understanding of the present disclosure. However, it is apparent to those skilled in the art that the present disclosure may be practiced without one or more of these details. In other examples, in order to avoid confusing with the present disclosure, some technical features well-known in the art are not described; that is, not all features of actual examples are described herein, and well-known functions and structures are not described in detail.

In the drawings, sizes and relative sizes of layers, areas and elements may be exaggerated for clarity. Like reference numerals denote like elements throughout the specification.

It should be understood that, spatially relative terms, such as “beneath”, “below”, “lower”, “under”, “over”, “upper”, and the like, may be used herein for ease of description to describe the relationship between one element or feature and other elements or features as illustrated in the figures. It should be understood that, the spatially relative terms are intended to further encompass different orientations of a device in use or operation in addition to the orientation depicted in the figures. For example, if a device in the drawings is turned over, then an element or a feature described as “below other elements”, or “under other elements”, or “beneath other elements” will be orientated to be “above” the other elements or features. Thus, the example terms, “below” and “beneath”, may include both upper and lower orientations. The device may be orientated otherwise (rotated by 90 degrees or other orientations), and the spatial descriptors used herein are interpreted accordingly.

The terms used herein are only intended to describe the specific examples, and are not used as limitations of the present disclosure. As used herein, unless otherwise indicated expressly in the context, “a”, “an” and “the” in a singular form are also intended to include a plural form. It should also be understood that the terms “consist of” and/or “comprise”, when used in this specification, determine the presence of a feature, integer, step, operation, element and/or component, but do not preclude the presence or addition of one or more of other features, integers, steps, operations, elements, components, and/or groups. As used herein, the term “and/or” includes any and all combinations of the listed relevant items.

In order to be capable of understanding the characteristics and the technical contents of the examples of the present disclosure in more detail, implementation of the examples of the present disclosure is set forth in detail below in conjunction with the drawings, and the appended drawings are only used for reference and illustration, instead of being used to limit the examples of the present disclosure.

In order to understand the present disclosure thoroughly, detailed operations and detailed structures will be proposed in the following descriptions so as to set forth the technical solution of the present disclosure. The detailed descriptions of the examples of the present disclosure are as follows. However, the present disclosure may also have other implementations in addition to these detailed descriptions.

The term “substrate” herein refers to a material onto which subsequent material layers are added. The substrate itself can be patterned. Materials added on the substrate can be patterned or can remain unpatterned.

The term “layer” herein refers to a material portion including a region with a certain thickness. A layer can extend over the entirety of an underlying structure or an overlying structure, or can have an extent less than the extent of an underlying structure or an overlying structure. Further, a layer can be a region of a homogeneous or inhomogeneous continuous structure that has a thickness less than that of the continuous structure.

The semiconductor structure in the examples of the present disclosure includes, but is not limited to, a 3D NAND memory. For case of understanding, the 3D NAND memory is taken as an example for illustration.

With the development of the semiconductor technology, the size of the 3D NAND memory develops in a trend of miniaturization, and the storage capacity of the memory is continuously increasing. On the one hand, in order to miniaturize the size of the memory, one or more deck structures of the memory may be formed by means of bonding, and each deck structure may comprise a memory cell array, a peripheral circuit, an interconnection structure and the like. In an example, the peripheral circuits and the memory cell arrays are formed in different wafers respectively, and the different wafers are connected in stacks through bonding. As such, the size of the memory can be miniaturized without changing the storage capacity. On the other hand, in order to increase the capacity of the memory, a plurality of deck structures may be disposed in the memory, and may be bonded in stacks by means of stacking to form a memory with a vertical structure. As such, the density or storage capacity of the memory can be improved while ensuring the performance of the memory.

The plurality of deck structures can be bonded in stacks by various means. In an example, as shown in FIG. 1, a memory 100 may comprise a plurality of deck structures 101, wherein through silicon vias (TSVs) 102 penetrating through each deck structure 101 are disposed in the deck structure 101, and a plurality of the through silicon vias 102 are connected through micro bumps 103, so as to achieve conduction between the plurality of deck structures 101. In some other examples, the vertical structure may be formed by using a pyramid-type deck packaging mode (i.e., the plurality of deck structures are connected for conduction through soldering wires); or spacer chips are added between the plurality of deck structures to achieve vertical connection of the plurality of deck structures. Based on the current technical development, the vertical connection of the plurality of deck structures are usually achieved by using the through silicon vias.

However, the through silicon vias TSV penetrating through each deck structure are usually formed by one etching, i.e., the vias penetrating through the deck structures are formed by one etching, and a conductive material is deposited in the vias to form the through silicon vias TSV. That is to say, different wafers disposed in stacks in each deck structure are all required to be etched in one etching process. It should be understood that, each wafer may include a plurality of layers, and since the materials of the plurality of layers are different, the compatibility between the vias and each wafer is low; in addition, due to the large thicknesses of the deck structures, aspect ratios of the vias formed by one etching are large, which increases the difficulty of the etching process.

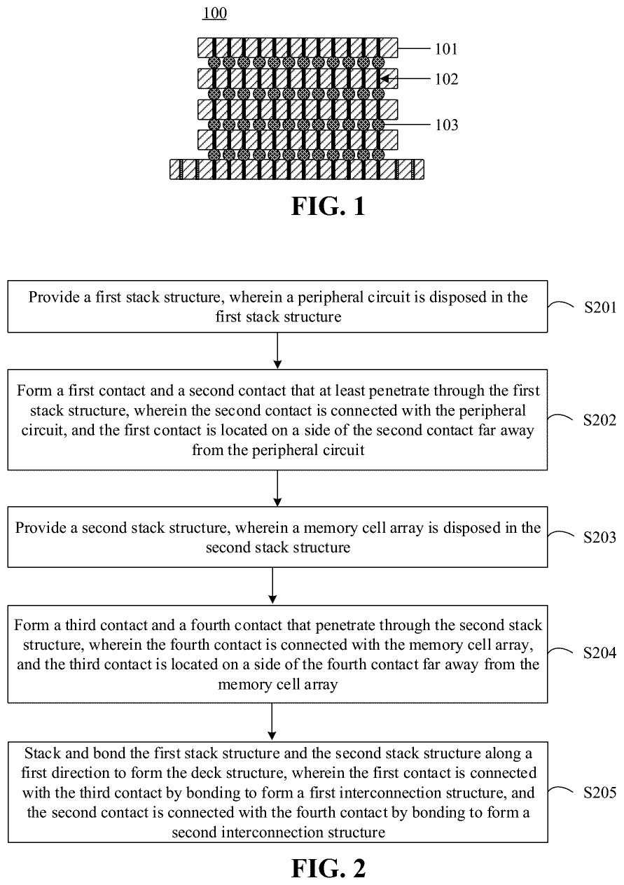

On that basis, in order to address one or more of the above problems, examples of the present disclosure propose a semiconductor structure and a fabrication method thereof, a memory device and a memory system. Referring to FIG. 2, FIG. 2 shows a schematic flow diagram of a fabrication method of a semiconductor structure provided by examples of the present disclosure. The semiconductor structure comprises at least one deck structure. The fabrication method of the deck structure comprises the following operations:
operation S201: providing a first stack structure, wherein a peripheral circuit is disposed in the first stack structure;
operation S202: forming a first contact and a second contact that at least penetrate through the first stack structure, wherein the second contact is connected with the peripheral circuit, and the first contact is located on a side of the second contact far away from the peripheral circuit;
operation S203: providing a second stack structure, wherein a memory cell array is disposed in the second stack structure;
operation S204: forming a third contact and a fourth contact that penetrate through the second stack structure, wherein the fourth contact is connected with the memory cell array, and the third contact is located on a side of the fourth contact far away from the memory cell array; and
operation S205: stacking and bonding the first stack structure and the second stack structure along a first direction to form the deck structure,
wherein the first contact is connected with the third contact by bonding to form a first interconnection structure, and the second contact is connected with the fourth contact by bonding to form a second interconnection structure.

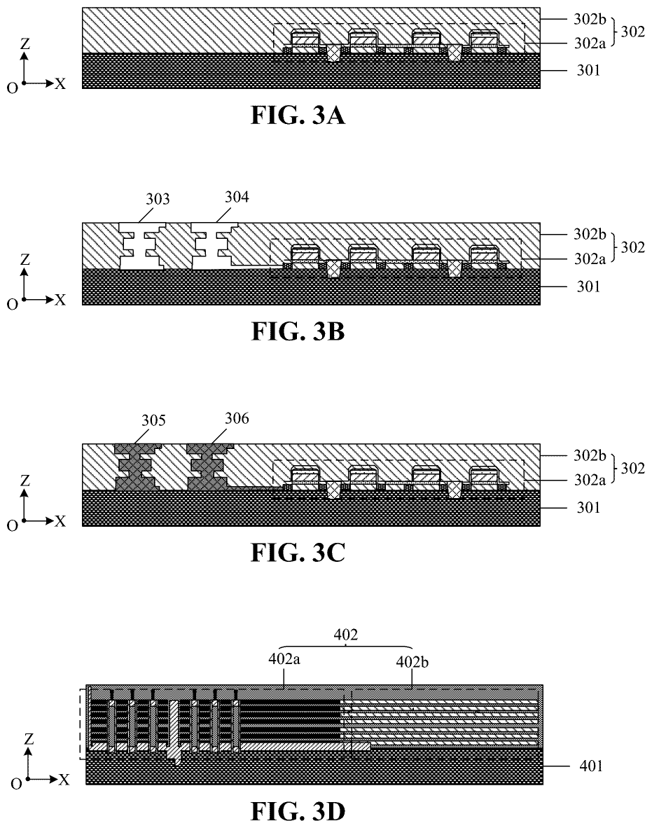

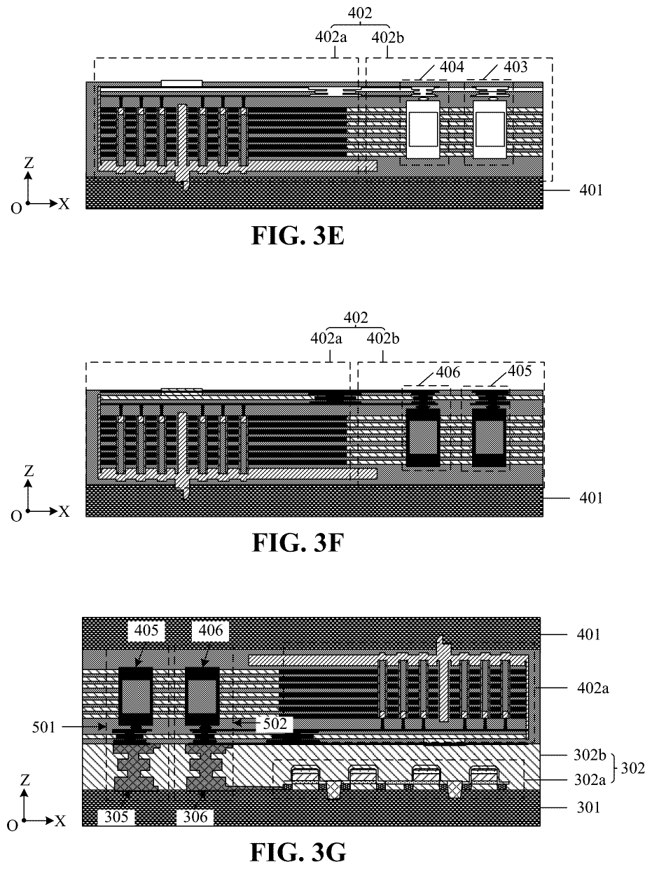

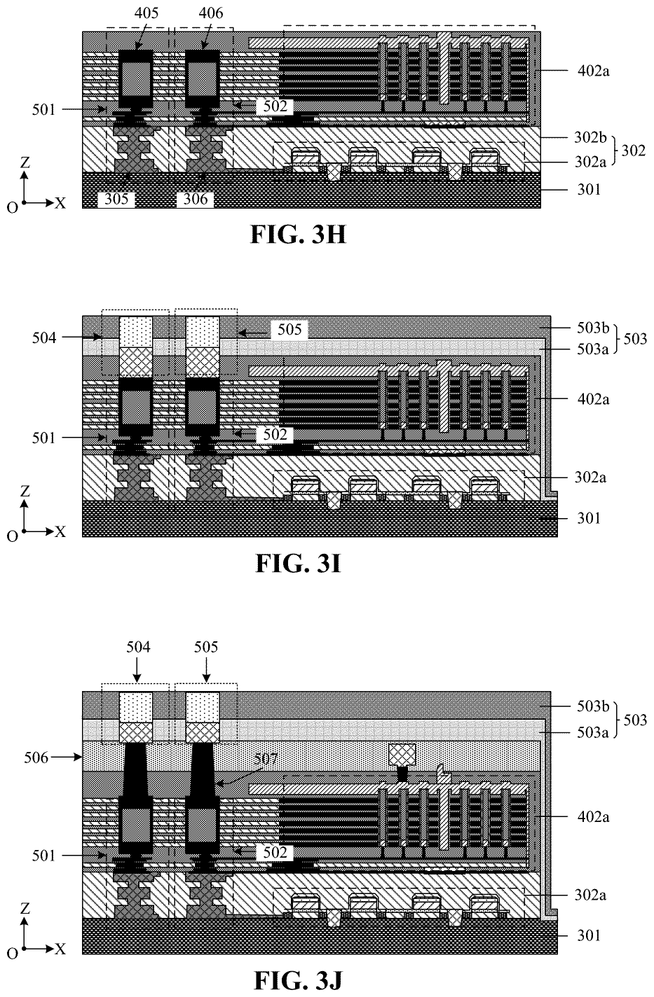

FIGS. 3A-3J are examples of cross-sectional views of a fabrication process of a semiconductor structure provided by examples of the present disclosure. It should be understood that the operations as shown in FIG. 2 are not exclusive, and other operations can also be performed before, after, or between any of the illustrated operations. A formation process of the semiconductor structure of this example is further described below in conjunction with FIGS. 2 and 3A-3J.

Operation S201 is performed to provide the first stack structure. In some examples, providing the first stack structure comprises: providing a first substrate, and forming the first stack structure on the first substrate.

Referring to FIG. 3A, FIG. 3A shows a schematic cross-sectional view of the first stack structure 302, wherein the first substrate 301 is provided, and the first substrate 301 may include an elemental semiconductor material substrate (e.g., a silicon (Si) substrate, a germanium (Ge) substrate, etc.), a composite semiconductor material substrate (e.g., a silicon germanium (SiGe) substrate, etc.), a silicon on insulator (SOI) substrate, a germanium on insulator (GeOI) substrate, etc. In an example, the first substrate 301 is a silicon substrate.

The first stack structure 302 may comprise a peripheral circuit 302a and a first dielectric layer 302b, wherein the peripheral circuit 302a may include at least one of any suitable digital, analog or hybrid signal circuit configured to facilitate a memory to achieve various operations such as reading operation, writing operation, erasing operation and the like. For example, the peripheral circuit may comprise a control logic (e.g., a control circuit or a controller), a data buffer, a decoder, a driver and a reading-writing circuit, etc. When the control logic receives a reading-writing operation command and address data, under the action of the control logic, the decoder may apply respective voltages obtained from the driver to respective bit lines and word lines based on decoded addresses to achieve reading and writing of data. The material of the first dielectric layer 302b includes, but is not limited to, silicon oxide, silicon nitride, silicon oxynitride, a low-k dielectric, or any combination thereof.

A method of forming the peripheral circuit 302a includes, but is not limited to, a deposition process and an etching process, wherein the deposition process includes chemical vapor deposition (CVD), physical vapor deposition (PVD), sputtering, or atomic layer deposition (ALD). In some examples, the deposition process further includes plasma-enhanced chemical vapor deposition (PECVD), metal-organic chemical vapor deposition (MOCVD), etc. The etching process includes dry etching, wet etching, etc. A method of forming the first dielectric layer 302b includes, but is not limited to, CVD, PVD and other processes.

Operation S202 is performed to form the first contact and the second contact that at least penetrate through the first stack structure.

In some examples, forming the first contact and the second contact that at least penetrate through the first stack structure comprises: forming a first via and a second via that penetrate through the first stack structure, wherein the first via and the second via are arranged along a second direction perpendicular to the first direction; and filling a first material in the first via and the second via to form the first contact and the second contact respectively.

In an example, referring to FIG. 3B, the first via 303 and the second via 304 penetrate through the first stack structure 302. In some other examples, at least one of the first via 303 or the second via 304 may also penetrate through the first substrate 301. Here, the first via 303 and the second via 304 are arranged along the second direction, and the second via 304 is connected with the peripheral circuit 302a. The first via 303 is located on a side of the second via 304 far away from the peripheral circuit 302a. In other words, the first via 303, the second via 304 and the peripheral circuit 302a are arranged in juxtaposition along the second direction sequentially. The shapes of the first via 303 and the second via 304 may include a cylinder, a rectangle, a square or any combination thereof, and may also include any suitable shape that is set according to actual situations. Here, a radial width of the first via along the second direction and a radial width of the second via along the second direction may be the same, and may also be different. A method of forming the first via 303 and the second via 304 includes, but is not limited to, plasma dry etching. In addition, in a process of forming the first via 303 and the second via 304, according to different materials (e.g., in the first dielectric layer) in the first stack structure, different etching parameters may be selected. As such, the precision of critical sizes of the first via 303 and the second via 304 can be improved.

Next, referring to FIG. 3C, the first material is filled in the first via 303 and the second via 304 through a deposition process to form the first contact 305 and the second contact 306 respectively. The deposition process includes, but is not limited to, CVD, PVD and other processes. The first material includes a conductive material, including, but not limited to, tungsten (W), cobalt (Co), copper (Cu), aluminum (Al), silicides, or any combination thereof. It is to be noted that, the materials filled in the first via 303 and the second via 304 may be the same and may also be different. For example, the first material is deposited in the first via 303, and other conductive material is deposited in the second via 304. Here, in order to reduce manufacturing processes, the first material is deposited in both the first via 303 and the second via 304.

Here and below, the first direction is perpendicular to the second direction. In an example, the first direction is a Z axis direction, and the second direction may be an X axis direction or a Y axis direction. For case of clear and concise description, the first direction is the Z axis direction and the second direction is the X axis direction as an example in each of the drawings.

Operation S203 is performed to provide the second stack structure. In some examples, providing the stack structure comprises: providing a second substrate, and forming the second stack structure on the second substrate.

Referring to FIG. 3D, FIG. 3D shows a schematic cross-sectional view of the second stack structure 402, wherein the second substrate 401 is provided and may be the same as the first substrate 301, which is no longer repeated here. The second stack structure 402 may comprise a memory cell array 402a and an interconnection layer 402b connected with the memory cell array, wherein the memory cell array may comprise a plurality of memory dies; each memory die may comprise a plurality of memory planes; each of the memory plane may comprise a plurality of memory blocks; each memory block may comprise a plurality of memory pages; each memory page may comprise a plurality of memory cells; and each memory cell may be programmed and store one or more bits of data. In some specific examples, each memory block may be coupled to a plurality of word lines; a plurality of memory cells coupled to each separately controlled word line constitute a memory page, and all memory cells coupled to each memory page constitute a memory cell layer. It is to be noted that, a plurality of memory cells are provided in a form of an array of NAND memory strings, and each NAND memory string extends above the second substrate along the Y axis direction. In some implementations, each NAND memory string comprises a plurality of memory cells that are coupled in series and stacked vertically. Here, each memory cell can hold a continuous analog value, such as a voltage or charge, which depends on the number of electrons trapped within a region of the memory cell. Each memory cell may be either a floating gate memory cell that includes a floating gate transistor, or a charge trapping memory cell that includes a charge trapping transistor.

Operation S204 is performed to form the third contact and the fourth contact that penetrate through the second stack structure. In some examples, forming the third contact and the fourth contact that penetrate through the second stack structure comprises: forming a third via and a fourth via that penetrate through the second stack structure, wherein the third via and the fourth via are arranged along the second direction; and filling a second material in the third via and the fourth via to form the third contact and the fourth contact respectively.

In an example, referring to FIG. 3E, the third via 403 and the fourth via 404 penetrate through an interconnection layer 402b of the second stack structure. In some other examples, at least one of the third via 403 or the fourth via 404 may also penetrate through the second substrate 401. Here, the third via 403 and the fourth via 404 are arranged along the second direction, and the fourth via 404 is connected with the memory cell array 402a through the interconnection layer 402b. The third via 403 is located on a side of the fourth via 404 far away from the memory cell array 402a. In other words, the third via 403, the fourth via 404 and the memory cell array 402a are arranged in juxtaposition along the second direction sequentially. The shapes of the third via 403 and the fourth via 404 may include a cylinder, a rectangle, a square or any combination thereof, and may also include any suitable shape that is set according to actual situations. Here, a radial width of the third via along the second direction and a radial width of the fourth via along the second direction may be the same, and may also be different. A method of forming the third via 403 and the fourth via 404 includes, but is not limited to, plasma dry etching. In addition, in a process of forming the third via 403 and the fourth via 404, according to different materials in the second stack structure, different etching parameters may be selected. As such, the precision of critical sizes of the third via 403 and the fourth via 404 can be improved.

It is to be noted that, other contacts or interconnection structures may also be formed in the second stack structure, which is not defined here. In addition, according to the process requirements, the radial width of the first via along the second direction and the radial width of the third via along the second direction may be the same, and may also be different; the radial width of the second via along the second direction and the radial width of the fourth via along the second direction may be the same, and may also be different; and the shapes of the first via, the second via, the third via and the fourth via may be set according to actual requirements.

Next, referring to FIG. 3F, the second material is filled in the third via 403 and the fourth via 404 through a deposition process to form the third contact 405 and the fourth contact 406 respectively. The deposition process includes, but is not limited to, CVD, PVD and other processes. The second material includes a conductive material, including, but not limited to, tungsten, cobalt, copper, aluminum, silicides, or any combination thereof. It is to be noted that, the materials filled in the third via 403 and the fourth via 404 may be the same and may also be different. Here, in order to reduce the manufacturing processes, the second material is deposited in both the third via 403 and the fourth via 404. It is to be noted that, the first material and the second material may be the same, and may also be different.

It is to be understood that, operation S201 and operation S202 may be performed after performing operation S203 and operation S204, and may also be performed before performing operation S203 and operation S204.

Operation S205 is performed to form the deck structure. Referring to FIG. 3G, the first stack structure 302 and the second stack structure 402 are stacked and bonded along the first direction, such that the first contact 305 is connected with the third contact 405 by bonding to form the first interconnection structure 501, and the second contact 306 is connected with the fourth contact 406 by bonding to form the second interconnection structure 502. A contact surface where the first stack structure 302 is bonded to the second stack structure 402 is a bonding surface.

FIG. 3G shows that the first stack structure 302 is located below the second stack structure 402. In some other examples, the first stack structure 302 may be also located above the second stack structure 402.

Next, referring to FIG. 3H, the method further comprises: thinning the first substrate 301 or removing the first substrate 301 which may be achieved through a chemical mechanical polishing (CMP) process. Removing the second substrate 401 or thinning the second substrate 401 may be also achieved through the chemical mechanical polishing (CMP) process.

Compared with forming the interconnection structures through one time of etching, the first interconnection structure/the second interconnection structure is formed through multiple times of etching in the examples of the present disclosure, such that the process difficulty of the etching can be reduced. Moreover, different etching parameters can be selected according to different materials in the stack structures, such that the compatibility of the first interconnection structure with the first stack structure can be improved, and the compatibility of the second interconnection structure with the second stack structure can also be improved. Furthermore, a radial width or a critical size of at least one of the first interconnection structure or the second interconnection structure may be also selected according to actual requirements.

In some examples, the method further comprises: forming a protective layer on a side of the second stack structure far away from the first stack structure after performing the bonding; and forming a fifth contact and a sixth contact that penetrate through the protective layer and are arranged along the second direction perpendicular to the first direction, wherein the fifth contact is connected with the first interconnection structure, and the sixth contact is connected with the second interconnection structure.

Referring to FIG. 3I, the protective layer 503 is formed on the side of the second stack structure 402 far away from the first stack structure after removing the second substrate, wherein the protective layer 503 may comprise a first protective sub-layer 503a and a second protective sub-layer 503b covering the first protective sub-layer 503a. Forming the protective layer 503 comprises: forming the first protective sub-layer 503a covering a side surface of the second stack structure 402 far away from the first stack structure; and forming the second protective sub-layer 503b covering the first protective sub-layer 503a. Here, the material of the first protective sub-layer 503a includes, but is not limited to, nitride, such as silicon nitride. A method of forming the first protective sub-layer 503a includes, but is not limited to, CVD, PVD and other processes. The material of the second protective sub-layer 503b includes, but is not limited to, organic resin, and a method of forming the second protective sub-layer 503b includes, but is not limited to, a coating process.

Next, a fifth via and a sixth via that penetrate through the first protective sub-layer 503a and the second protective sub-layer 503b are formed, wherein the fifth via and the sixth via are arranged along the second direction, and a method of forming the fifth via and the sixth via includes, but is not limited to, plasma dry etching. Here, a radial width of the fifth via along the second direction and a radial width of the sixth via along the second direction may be the same, and may also be different. Next, a third material is deposited in the fifth via and the sixth via to form the fifth contact 504 and the sixth contact 505 respectively. The shapes of the fifth via and the sixth via may be selected and set according to actual requirements. Here, the third material includes a conductive material, including, but not limited to, tungsten, cobalt, copper, aluminum, silicides, or any combination thereof. It is to be noted that, the materials filled in the fifth via and the sixth via may be the same and may also be different. Here, in order to reduce the manufacturing processes, the third material is deposited in both the fifth via and the sixth via. In examples of the present disclosure, the fifth contact 504 is connected with the first interconnection structure 501 to form a first through-structure, and the sixth contact 505 is connected with the second interconnection structure 502 to form a second through-structure.

In some examples, referring to FIG. 3J, the deck structure further comprises a second dielectric layer 506, and third interconnection structures 507 penetrating through the second dielectric layer. Forming the protective layer 503 on the side of the second stack structure 402 far away from the first stack structure comprises: forming the second dielectric layer 506 on the side of the second stack structure 402 far away from the first stack structure, and forming the first protective sub-layer 503a on the second dielectric layer 506 and the second protective sub-layer 503b covering the first protective sub-layer 503a. The material of the second dielectric layer 506 includes, but is not limited to, silicon nitride; and a method of forming the second dielectric layer includes, but is not limited to, CVD. PVD, or the like. The method of forming the second protective sub-layer 503b covering the first protective sub-layer 503a has been mentioned previously, which is no longer repeated here. Here, the fifth contact 504 is connected with the first interconnection structure 501 through one of the third interconnection structures 507 to form the first through-structure, and the sixth contact 505 is connected with the second interconnection structure 502 through the other one of the third interconnection structures 507 to form the second through-structure.

As such, the through-structures penetrating through the entire deck structure may be formed. In other words, multiple contacts are formed through multiple times of etching and filling, and the multiple contacts are connected by bonding to form the through-structures penetrating through the entire deck structure, which may reduce the process difficulty of the etching and improve the compatibility of the through-structures with the deck structure, thus improving the reliability of the semiconductor structure.

In some examples, the semiconductor structure comprises a plurality of the deck structures, wherein a formation method of each of the plurality of deck structures is the same, and the plurality of deck structures include one first deck structure and a plurality of second deck structures. The method further comprises: stacking and bonding the one first deck structure and the plurality of second deck structures along the first direction sequentially,
wherein the protective layer of the first deck structure is connected with the protective layer of an adjacent one of the second deck structures, and for every two adjacent second deck structures of the plurality of second deck structures, the protective layer of one of the second deck structures is connected with the first stack structure in the other one of the second deck structures; and
the first interconnection structures in the first deck structure and the plurality of second deck structures are connected with each other through the fifth contacts, and the second interconnection structures in the first deck structure and the plurality of second deck structures are connected with each other through the sixth contacts.

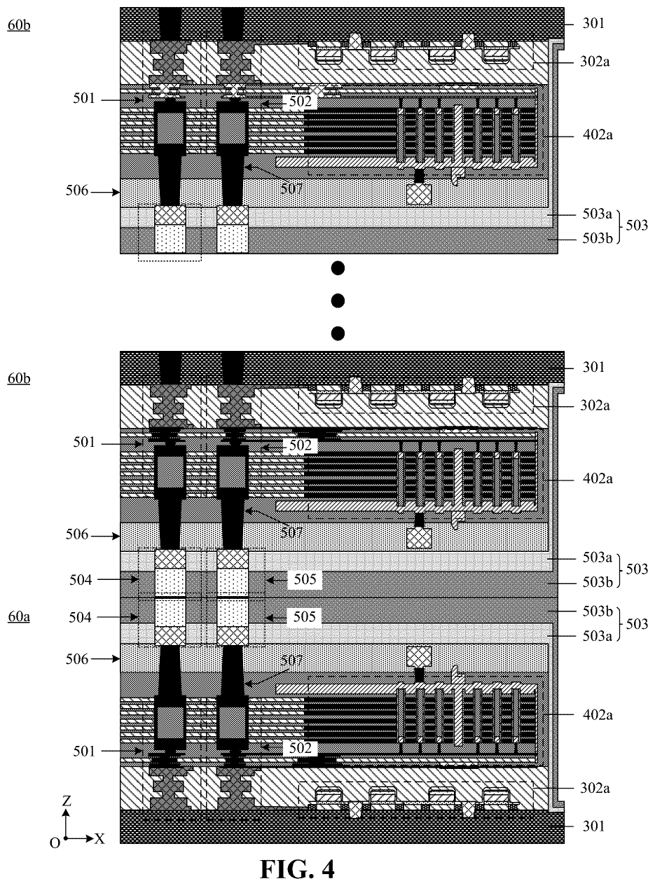

In an example, referring to FIG. 4, the plurality of deck structures include one first deck structure 60a and the plurality of second deck structures 60b, wherein the first deck structure 60a and the second deck structures 60b differ only in that both the first contact (the first interconnection structure 501) and the second contact (the second interconnection structure 502) of the first deck structure do not penetrate through the first substrate 301, and both the first contact (the first interconnection structure 501) and the second contact (the second interconnection structure 502) of each of the plurality of second deck structures 60b penetrate through the first substrate. However, it should be understood that whether the first interconnection structure 501 and the second interconnection structure 502 are needed to penetrate through the first substrate 301 may be selected and set according to actual requirements.

Referring to FIG. 4, in the semiconductor structure, the protective layer 503 of the first deck structure 60a is connected with the protective layer 503 of an adjacent one of the second deck structures 60b, and the fifth contact 504 in the first deck structure 60a is connected with the fifth contact 504 in the adjacent one of the second deck structures 60b. As such, the interconnection between the first interconnection structure 501 in the first deck structure 60a and the first interconnection structure 501 in the second deck structure 60b is achieved by etching, thereby achieving conductive connection between the deck structures. Likewise, the sixth contact 505 in the first deck structure 60a is connected with the sixth contact 505 in an adjacent one of the second deck structures 60b. As such, the interconnection between the second interconnection structure 502 in the first deck structure 60a and the second interconnection structure 502 in the second deck structure 60b is achieved by etching. Accordingly, on the one hand, the conductive connection between the deck structures can be achieved; on the other hand, the interconnection between the memory cell arrays and the peripheral circuits in the plurality of deck structures can also be achieved.

Further, the plurality of second deck structures 60b are connected by bonding on a side of the second deck structure 60b adjacent to the first deck structure 60a, such that the semiconductor structure may have a larger storage capacity. In the plurality of second deck structures, the first interconnection structures are connected with each other through the fifth contacts, and the second interconnection structures are connected with each other through the sixth contacts. As such, the conductive connection between the deck structures can be achieved, and the storage density of the semiconductor structure can also be increased while minimizing the structure size of the semiconductor structure.

In another aspect, based on the above formation method of the semiconductor structure, examples of the present disclosure further provide a semiconductor structure comprising: at least one deck structure comprising a first stack structure and a second stack structure that are disposed in a stack along a first direction, wherein a peripheral circuit is disposed in the first stack structure, and a memory cell array is disposed in the second stack structure;
a first contact and a second contact that at least penetrate through the first stack structure, wherein the second contact is connected with the peripheral circuit, and the first contact is located on a side of the second contact far away from the peripheral circuit; and
a third contact and a fourth contact that penetrate through the second stack structure, wherein the fourth contact is connected with the memory cell array, and the third contact is located on a side of the fourth contact far away from the memory cell array,
wherein the first contact is connected with the third contact by bonding to constitute a first interconnection structure, and the second contact is connected with the fourth contact by bonding to constitute a second interconnection structure.

In some examples, a composition material of the first contact is the same as a composition material of the second contact.

In some examples, the composition material of the first contact is different from the composition material of the second contact.

In some examples, the composition material of the first contact includes copper, and the composition material of the second contact includes tungsten.

In some examples, the deck structure further comprises:
a protective layer on a side of the second stack structure far away from the first stack structure; and
a fifth contact and a sixth contact each penetrating through the protective layer and being arranged along a second direction perpendicular to the first direction,
wherein the fifth contact is connected with the first interconnection structure, and the sixth contact is connected with the second interconnection structure.

In some examples, the deck structures comprise a plurality of the deck structures comprising one first deck structure and a plurality of second deck structures which are disposed in stacks along the first direction sequentially,
wherein the protective layer of the first deck structure is connected with the protective layer of an adjacent one of the second deck structures, and for every two adjacent second deck structures of the plurality of second deck structures, the protective layer of one of the second deck structures is connected with the first stack structure in the other one of the second deck structures; and
each of the first interconnection structures in the first deck structure and the plurality of second deck structures is connected through the fifth contact, and each of the second interconnection structures in the first deck structure and the plurality of second deck structures is connected through the sixth contact.

Examples of the present disclosure further provide a memory device comprising: the semiconductor structure as described in the above examples of the present disclosure.

Examples of the present disclosure further provide a memory system comprising: the memory device as described in the above examples of the present disclosure; and
a memory controller connected with the memory device and configured to control the memory device.

It should be understood that, references to “one example” or “an example” throughout this specification mean that particular features, structures, or characteristics related to the example are included in at least one example of the present disclosure. Therefore, “in one example” or “in an example” presented throughout this specification does not necessarily refer to the same example. Furthermore, these particular features, structures, or characteristics may be incorporated in one or more examples in any suitable manner. It should be understood that, in various examples of the present disclosure, sequence numbers of the above-mentioned processes do not indicate an execution sequence, and an execution sequence of various processes should be determined by functionalities and intrinsic logics thereof, and should constitute no limitation on implementations of the examples of the present disclosure. The above sequence numbers of the examples of the present disclosure are only for description, and do not represent advantages or disadvantages of the examples.

The methods disclosed in several method examples as provided by the present disclosure may be combined freely to obtain new method examples in case of no conflicts.

In order to address the relevant technical problems, examples of the present disclosure propose a semiconductor structure and a fabrication method thereof, a memory device and a memory system. Examples of the present disclosure provide a semiconductor structure which comprises at least one deck structure. The fabrication method of the deck structure comprises:
providing a first stack structure that comprises a peripheral circuit;
forming a first contact and a second contact that at least penetrate through the first stack structure, wherein the second contact is connected with the peripheral circuit, and the first contact is located on a side of the second contact far away from the peripheral circuit;
providing a second stack structure that comprises a memory cell array;
forming a third contact and a fourth contact that penetrate through the second stack structure, wherein the fourth contact is connected with the memory cell array, and the third contact is located on a side of the fourth contact far away from the memory cell array; and
stacking and bonding the first stack structure and the second stack structure along a first direction to form the deck structure,
wherein the first contact is connected with the third contact by bonding to form a first interconnection structure, and the second contact is connected with the fourth contact by bonding to form a second interconnection structure.

In one implementation, forming the first contact and the second contact that at least penetrate through the first stack structure comprises: forming respectively a first via and a second via that penetrate through the first stack structure, wherein the first via and the second via are arranged along a second direction perpendicular to the first direction; and filling a first material in the first via and the second via to form the first contact and the second contact respectively; and
forming the third contact and the fourth contact that penetrate through the second stack structure comprises: forming respectively a third via and a fourth via that penetrate through the second stack structure, wherein the third via and the fourth via are arranged along the second direction; and filling a second material in the third via and the fourth via to form the third contact and the fourth contact respectively.

In one implementation, the first material is the same as the second material.

In one implementation, the first material is different from the second material.

In one implementation, the first material includes copper, and the second material includes tungsten.

In one implementation, the method further comprises: forming a protective layer on a side of the second stack structure far away from the first stack structure after performing the bonding; and
forming a fifth contact and a sixth contact that penetrate through the protective layer and are arranged along a second direction perpendicular to the first direction,
wherein the fifth contact is connected with the first interconnection structure, and the sixth contact is connected with the second interconnection structure.

In one implementation, the semiconductor structure comprises a plurality of the deck structures that comprise one first deck structure and a plurality of second deck structures; and
the method further comprises: stacking and bonding the one first deck structure and the plurality of second deck structures along the first direction sequentially,
wherein the protective layer of the first deck structure is connected with the protective layer of an adjacent one of the second deck structures, and for every two adjacent second deck structures of the plurality of second deck structures, the protective layer of one of the second deck structures is connected with the first stack structure in the other one of the second deck structures; and
the first interconnection structures in the first deck structure and the plurality of second deck structures are connected with each other through the fifth contacts, and the second interconnection structures in the first deck structure and the plurality of second deck structures are connected with each other through the sixth contacts.

Examples of the present disclosure further provide a semiconductor structure comprising: at least one deck structure comprising a first stack structure and a second stack structure that are disposed in a stack along a first direction, wherein the first stack structure comprises a peripheral circuit, and the second stack structure comprises a memory cell array;
a first contact and a second contact that at least penetrate through the first stack structure, wherein the second contact is connected with the peripheral circuit, and the first contact is located on a side of the second contact far away from the peripheral circuit; and
a third contact and a fourth contact that penetrate through the second stack structure, wherein the fourth contact is connected with the memory cell array, and the third contact is located on a side of the fourth contact far away from the memory cell array,
wherein the first contact is connected with the third contact by bonding to constitute a first interconnection structure, and the second contact is connected with the fourth contact by bonding to constitute a second interconnection structure.

In one implementation, a composition material of the first contact is the same as a composition material of the second contact.

In one implementation, the composition material of the first contact is different from the composition material of the second contact.

In one implementation, the composition material of the first contact includes copper, and the composition material of the second contact includes tungsten.

In one implementation, the deck structure further comprises: a protective layer on a side of the second stack structure far away from the first stack structure; and
a fifth contact and a sixth contact each penetrating through the protective layer and being arranged along a second direction perpendicular to the first direction,
wherein the fifth contact is connected with the first interconnection structure, and the sixth contact is connected with the second interconnection structure.

In one implementation, the deck structures comprise a plurality of the deck structures comprising one first deck structure and a plurality of second deck structures which are disposed in stacks along the first direction sequentially,
wherein the protective layer of the first deck structure is connected with the protective layer of an adjacent one of the second deck structures, and for every two adjacent second deck structures of the plurality of second deck structures, the protective layer of one of the second deck structures is connected with the first stack structure in the other one of the second deck structures; and
each of the first interconnection structures in the first deck structure and the plurality of second deck structures is connected through the fifth contact, and each of the second interconnection structures in the first deck structure and the plurality of second deck structures is connected through the sixth contact.

Examples of the present disclosure further provide a memory device comprising: the semiconductor structure as described in the above implementations of the present disclosure.

Examples of the present disclosure further provide a memory system comprising: the memory device as described in the above implementations of the present disclosure; and
a memory controller connected with the memory device and configured to control the memory device.

Examples of the present disclosure propose a semiconductor structure and a fabrication method, a memory device, and a memory system. The semiconductor structure comprises: at least one deck structure. The fabrication method of the deck structure comprises: providing a first stack structure comprising a peripheral circuit; forming a first contact and a second contact that at least penetrate through the first stack structure, wherein the second contact is connected with the peripheral circuit, and the first contact is located on a side of the second contact far away from the peripheral circuit; providing a second stack structure comprising a memory cell array; forming a third contact and a fourth contact that penetrate through the second stack structure, wherein the fourth contact is connected with the memory cell array, and the third contact is located on a side of the fourth contact far away from the memory cell array; stacking and bonding the first stack structure and the second stack structure along a first direction to form the deck structure, wherein the first contact is connected with the third contact by bonding to form a first interconnection structure, and the second contact is connected with the fourth contact by bonding to form a second interconnection structure. In other words, in examples of the present disclosure, the first contact and the second contact are formed in the first stack structure, the third contact and the fourth contact are formed in the second stack structure. Then the first stack structure and the second stack structure are bonded, such that the first contact is connected with the third contact to form the first interconnection structure, and the second contact is connected with the fourth contact to form the second interconnection structure. As such, the first interconnection structure may be formed by means of forming the first contact and the third contact separately, thereby reducing the process difficulty of forming the first interconnection structure and improving the compatibility of the first interconnection structure with the first stack structure. Likewise, the second interconnection structure is formed by means of forming the second contact and the fourth contact separately, which can also reduce the process difficulty of forming the second interconnection structure and improve the compatibility of the second interconnection structure with the second stack structure, thereby improving the reliability of the semiconductor structure.

The above descriptions are merely specific implementations of the present disclosure, and the protection scope of the present disclosure is not limited to these. Any variation or replacement that may be readily figured out by those skilled in the art within the technical scope disclosed by the present disclosure shall fall within the protection scope of the present disclosure. Therefore, the protection scope of the present disclosure shall be defined by the protection scope of the claims.

What is claimed is:

1. A fabrication method of a semiconductor structure, wherein the semiconductor structure includes at least one deck structure, and a fabrication method of the deck structure comprises:
providing a first stack structure, wherein a peripheral circuit is disposed in the first stack structure;
forming a first contact and a second contact that at least penetrate through the first stack structure, wherein the second contact is connected with the peripheral circuit, and the first contact is located on a side of the second contact far away from the peripheral circuit;
providing a second stack structure, wherein a memory cell array is disposed in the second stack structure;
forming a third contact and a fourth contact that penetrate through the second stack structure, wherein the fourth contact is connected with the memory cell array, and the third contact is located on a side of the fourth contact far away from the memory cell array; and
stacking and bonding the first stack structure and the second stack structure along a first direction to form the deck structure,
wherein the first contact is connected with the third contact by bonding to form a first interconnection structure, and the second contact is connected with the fourth contact by bonding to form a second interconnection structure.

2. The fabrication method of claim 1, wherein
forming the first contact and the second contact that at least penetrate through the first stack structure comprises: forming respectively a first via and a second via that penetrate through the first stack structure, wherein the first via and the second via are arranged along a second direction perpendicular to the first direction; and filling a first material in the first via and the second via to form the first contact and the second contact respectively; and
forming the third contact and the fourth contact that penetrate through the second stack structure comprises: forming respectively a third via and a fourth via that penetrate through the second stack structure, wherein the third via and the fourth via are arranged along the second direction; and filling a second material in the third via and the fourth via to form the third contact and the fourth contact respectively.

3. The fabrication method of claim 2, wherein the first material is the same as the second material.

4. The fabrication method of claim 2, wherein the first material is different from the second material.

5. The fabrication method of claim 4, wherein the first material includes copper, and the second material includes tungsten.

6. The fabrication method of claim 1, further comprising:
forming a protective layer on a side of the second stack structure far away from the first stack structure after performing the bonding; and
forming a fifth contact and a sixth contact that penetrate through the protective layer and are arranged along a second direction perpendicular to the first direction,
wherein the fifth contact is connected with the first interconnection structure, and the sixth contact is connected with the second interconnection structure.

7. The fabrication method of claim 6, wherein the semiconductor structure comprises a plurality of the deck structures that comprise one first deck structure and a plurality of second deck structures; and
the fabrication method further comprises: stacking and bonding the one first deck structure and the plurality of second deck structures along the first direction sequentially,
wherein the protective layer of the first deck structure is connected with the protective layer of an adjacent one of the second deck structures, and for every two adjacent second deck structures of the plurality of second deck structures, the protective layer of one of the second deck structures is connected with the first stack structure in the other one of the second deck structures; and
the first interconnection structures in the first deck structure and the plurality of second deck structures are connected with each other through the fifth contacts, and the second interconnection structures in the first deck structure and the plurality of second deck structures are connected with each other through the sixth contacts.

8. A semiconductor structure including a deck structure, the deck structure comprising:
a first stack structure and a second stack structure that are disposed in a stack along a first direction, wherein a peripheral circuit is disposed in the first stack structure, and a memory cell array is disposed in the second stack structure;
a first contact and a second contact that at least penetrate through the first stack structure, wherein the second contact is connected with the peripheral circuit, and the first contact is located on a side of the second contact far away from the peripheral circuit; and
a third contact and a fourth contact that penetrate through the second stack structure, wherein the fourth contact is connected with the memory cell array, and the third contact is located on a side of the fourth contact far away from the memory cell array,
wherein the first contact is connected with the third contact by bonding to constitute a first interconnection structure, and the second contact is connected with the fourth contact by bonding to constitute a second interconnection structure.

9. The semiconductor structure of claim 8, wherein a composition material of the first contact is the same as a composition material of the second contact.

10. The semiconductor structure of claim 8, wherein a composition material of the first contact is different from a composition material of the second contact.

11. The semiconductor structure of claim 10, wherein the composition material of the first contact includes copper, and the composition material of the second contact includes tungsten.

12. The semiconductor structure of claim 11, wherein the deck structure further comprises:
a protective layer on a side of the second stack structure far away from the first stack structure; and
a fifth contact and a sixth contact each penetrating through the protective layer and being arranged along a second direction perpendicular to the first direction,
wherein the fifth contact is connected with the first interconnection structure, and the sixth contact is connected with the second interconnection structure.

13. The semiconductor structure of claim 12, wherein the deck structure comprises a plurality of the deck structures comprising one first deck structure and a plurality of second deck structures which are disposed in stacks along the first direction sequentially,
wherein the protective layer of the first deck structure is connected with the protective layer of an adjacent one of the second deck structures, and for every two adjacent second deck structures of the plurality of second deck structures, the protective layer of one of the second deck structures is connected with the first stack structure in the other one of the second deck structures; and
each of the first interconnection structures in the first deck structure and the plurality of second deck structures is connected through the fifth contact, and each of the second interconnection structures in the first deck structure and the plurality of second deck structures is connected through the sixth contact.

14. A memory system, comprising:
a memory device comprising:
a semiconductor structure comprising:
at least one deck structure comprising:
a first stack structure and a second stack structure that are disposed in a stack along a first direction, wherein a peripheral circuit is disposed in the first stack structure, and a memory cell array is disposed in the second stack structure;
a first contact and a second contact that at least penetrate through the first stack structure, wherein the second contact is connected with the peripheral circuit, and the first contact is located on a side of the second contact far away from the peripheral circuit; and
a third contact and a fourth contact that penetrate through the second stack structure, wherein the fourth contact is connected with the memory cell array, and the third contact is located on a side of the fourth contact far away from the memory cell array,
wherein the first contact is connected with the third contact by bonding to constitute a first interconnection structure, and the second contact is connected with the fourth contact by bonding to constitute a second interconnection structure; and
a memory controller connected with the memory device and configured to control the memory device.
